(19) United States
(12) Patent Application Publication
(10) Pub. No.: US 2005/0099196 A1
(43) Pub. Date: May 12, 2005

(54) Semiconductor inspection device based on use of probe information, and semiconductor inspection method

(75) Inventor: Tomohide Sasaki, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 10/985,991

(22) Filed: Nov. 12, 2004

(30) Foreign Application Priority Data
Nov. 12, 2003 (JP) 2003-382518

(51) Int. Cl. G01R 31/26

(52) U.S. Cl. 324/754

(57) ABSTRACT

A semiconductor inspection device and a method of inspection capable of reducing labor for species registration using a prober and of improving operation rate of the prober. The semiconductor inspection device based on use of probe information makes a prober 8 recognize probe information of a probe card 1 measured using a card checker 3 or the like, and the prober 8 automatically recognizes position and height of all probe needles correspondent to electrode pads, by making coincidence of a reference position of an LSI chip with a reference position of said probe information.

This application is based on Japanese patent application No. 2003-382518 the content of which is incorporated hereinto by reference.

### DISCLOSURE OF THE INVENTION

1. Field of the Invention

The present invention relates to a semiconductor inspection device based on use of probe information, and a semiconductor inspection method, and more specifically to a wafer handling device (prober) used in a semiconductor inspection method (wafer test), and in particular to a probing technique for wafers, species registration works on the prober, and probe card management.

2. Related Art

In fabrication process of semiconductor devices, wafers having LSI chips formed thereon by the wafer fabrication process are subjected to a test (referred to as “wafer test”, hereinafter). In the wafer test, electrical measurements are made on open/short circuit and input/output characteristics of electrode patterns, to thereby judge acceptance or rejection of the LSI chips in a wafer form. The technique is to make probe needles contact with electrode pads of an LSI chip, so as to connect the probe needles through a probe card and a contact ring to a tester. This makes it possible to carry out electrical measurement of the electrode pads using a tester through the probe needle (see Japanese Laid-Open Patent Publication No. 61-171145, for example).

With progress of thinning and shrinkage of LSI chips, recent wafer test raises fears of an excessive damage on the LSI chips, and misalignment of the contact positions on the LSI chip. To sweep the fears away, it is essential to exactly understand properties of the probe card, such as probe needle location or probe needle height for example, and there is a demand for such prober.

In the wafer test, the prober registers the LSI chip and the probe card (species registration). The species registration is necessary every time a new species is measured, wherein length of time for the registration depends on items to be registered, and operation for the registration, during which the prober is kept in an idle state, degrades the operation rate. This raises a demand of shortening the operation time of the species registration, and a demand for such prober.

In the wafer test, as shown in FIG. 6, probe needles 104 provided to a probe card 103 are brought into contact with electrode pads formed on the LSI chips in a wafer 106 held on a wafer stage 107, wherein the electrical measurement of the LSI chips is made by a test head 101 through a contact ring 102.

Next paragraphs will describe a process flow of the species registration, which is as a preparatory process for the electrical measurement, referring to a flow chart shown in FIG. 5.

(1) Registration of Species Information (step S100 in FIG. 5)

Information of the LSI chip to be measured, and information of the probe card are entered to the prober.

(2) Transfer of Wafer (not illustrated)

The wafer 106 (see FIG. 6) housed in a wafer case is transferred onto the wafer stage 107.

(3) Thickness Measurement and Alignment of Transferred Wafer (step S110 in FIG. 5)

The wafer 106 placed on the wafer stage 107 shown in FIG. 6 is subjected to thickness measurement and alignment using an optical unit 108 such as a CCD camera or an electrostatic capacity sensor (not illustrated). The thickness measurement of the wafer 106 is made based on height difference between the surface of the wafer 106 and the surface of the wafer stage 107, which is obtained by processing of an image input by the optical unit, or by detection using an electrostatic capacity sensor.

In the alignment, θ alignment is first made by the prober using a characteristic pattern in the LSI chip on the wafer 106, such as a specific point or a reference mark (step S120 in FIG. 5). Next, the center of the wafer and a reference position of the LSI chip are measured based on the image input by the optical unit (step S130 in FIG. 5), a measurement position is calculated (step S140 in FIG. 5), and alignment is made also in the XY direction (step S150 in FIG. 5).

(4) Alignment of LSI Chip and Probe Needles (steps S150, S160 in FIG. 5)

Alignment of the electrode pads and the probe needles are available in two ways, that are a method of first registering positions of the electrode pads, and then aligning the probe needles so as to make coincidence of the positions of the probe needles with arrangement of the electrode pads, and conversely a method of first registering the positions of the probe needles, and then aligning the electrode pads so as to make coincidence of the positions of the electrode pads with arrangement of the probe needles. These methods of registration only differ in the order of registration but same in the processing per se. The description herein will be made on the method in which the electrode pads are registered first.

The alignment is made so that the probe ends 114 of the probe needles 112 shown in FIG. 8 are brought into contact with the electrode pads 111 of the LSI chip 110 as being corresponded as shown in FIG. 7. First, registration windows 113 are aligned with arbitrary electrode pads 111 to be registered, and positions of the electrode pads 111 to be registered are specified typically by coordinate values, on an image of this state incorporated by the optical unit (step S170 in FIG. 5).

In this process, the number of electrode pads 111 to be registered must be three or more, in view of aligning the electrode pads 111 with the ends 114 of the probe needles 112, and position of the electrode pads 111 are specified, and then the electrode pads 111 and probe needles 112 are aligned.

As shown in FIG. 8, the registration windows 115 are aligned with the ends 114 of the probe needles 112 correspondent to the arrangement of the electrode pads, so as to specify the positions of the ends 114 of the registered probe needles 112 (step 170 in FIG. 5). This makes it possible to calculate positions of the registered electrode pads 111 and probe ends 114 of the registered probe needles 112 based on the individual coordinates already registered (step S170 in FIG. 5), and to determine the positions (step S180 in FIG. 5).

Next, heights of the probe ends 114 of the registered probe needles 112 are detected based on the image entered by the optical unit. More specifically, heights of the probe ends 114 of the probe needles 112 same as those being previously aligned are detected based on the image entered by the optical unit (steps S190 to S220 in FIG. 5). An average value of thus-detected heights of the probe ends 114 is then calculated, and the height expressed in the average value is defined as a position where the first contact between the electrode pads 111 and the ends 114 of the probe needles 112 takes place. It is to be noted that the position where the first contact of the electrode pads 111 to the ends 114 takes place is defined as the center of the registration window 113.

(5) Confirmation of Probe Marks on Electrode Pads (not illustrated)

Positions of the electrode pads 111 of the LSI chip 110 shown in FIG. 7 and of the probe ends 114 of the probe needles 112 shown in FIG. 8 are confirmed by visually inspecting whether probe marks formed on the electrode pads through contact with the probe needles 112 fall in appropriate positions or not. The contact positions are corrected if necessary.

(6) Start of Measurement (step S230 in FIG. 5) Electrical measurement of the LSI chip is made by allowing the probe ends 114 of the probe needles 112 shown in FIG. 8 to contact with the electrode pads 111 of the LSI chip 110 shown in FIG. 7.

(7) Measurement of the Second Wafer and Thereafter (not illustrated)

The alignment and registration operations of the electrode pads of the LSI chip formed on the wafer 106 shown in FIG. 6 with the probe needles 104 provided to the probe card 103 have already finished using the first wafer, so that in the wafer measurement for the second wafer and thereafter, the alignment of the both is automatically made based on the coordinate values of the electrode pads and probe needles 104 registered in the measurement for the first wafer, and detection of height of the probe needles is automatically made, which is followed by the electrical measurement.

The above-described prior art, however, consumed a lot of time for the species registration because the operator manually registered the electrode pads or probe needles. The operation time necessary for the species registration herein depends on the number of electrode pads or probe needles to be registered.

With recent increase in the numbers of electrode pads per se and of LSI chips to be measured at a time due to increased processing speed of LSI chips, there is a demand of registering positions of a larger number of electrode pads or probe needles in order to ensure exact contact of the electrode pads with the probe needles. Registration of the positions of the electrode pads or probe needles are carried out by manually aligning the registration windows as described in the above, so that the positions of the registration windows vary from species to species, and this make the operation labor-consuming.

In the prior art, for the case where the electrode pads 111 at four arbitrary points are registered as shown in FIG. 9, the alignment is made with the probe needles correspondent with an arrangement 116 of these four points. An overall confirmation of the position must, however, be made using the probe marks formed on the electrode pads, because no positions of any probe needles other than those of the registered probe needles are taken into account. This inevitably needs confirmation of the probe marks, and this also leaves unnecessary probe marks on the electrode pads.

The prior art is also disadvantageous in that the prober detects height only for the registered probe needles, so that it cannot obtain any information on the height of unregistered probe needles. For an exemplary case where any of the registered needle 112 has a height 122 at the most distant position away from the probe card 103 as shown in FIG. 10, the prober recognizes an average value 118 of the heights of the probe needles as a height of all probe needles. This is undesirably causative of non-uniform contact between the probe needles 112 and electrode pads.

The prior art is still also disadvantageous in that the prober is incapable of managing the height of all probe needles. The registered probe needles are only matters manageable by the prior art.

The prior art is still also disadvantageous in that the prober cannot automatically obtain any information on positions of the probe needles correspondent to the electrode pads, so that it is necessary for the operator to specify positions of the electrode pads and probe needles in a predetermined correlation, referring to the design drawing. This may result in errors in the correspondence between the electrode pads and probe needles and misalignment of the contact position due to some mistakes in the operation.

### SUMMARY OF THE INVENTION

An aspect of the present invention may reside in that it may save labor in the species registration for the prober and can improve operation rate of the prober. Another aspect may reside in that it may reduce time necessary for the species registration of the electrode pads and probe needles, which is carried out on the prober. A further aspect may reside in that it enables management of the probe needles on the prober. A further aspect may reside in that it enables probing with understanding of state of all probe needles. A further aspect may reside in that unnecessary probe marks may not be formed on the electrode pads. A further aspect may reside in that the probe needles to be contact with the electrode pads may immediately be determined.

The present invention makes it possible to reduce labor in the species registration on the prober, and to improve operation rate of the prober.

### BRIEF DESCRIPTION OF THE DRAWINGS

The above and other objects, advantages and features of the present invention will be more apparent from the following description taken in conjunction with the accompanying drawings, in which:

FIG. 1 is a flow chart showing a process flow from entry of data with respective to the probe information up to inspection measurement using a prober according to the present invention;

FIG. 2 is a drawing showing a unit making the prober recognize probe information;

FIG. 3 is a drawing explaining alignment of an LSI chip with a probe card, according to the present invention;

FIG. 4 is a drawing showing a display of the probe information on the electrode pad, according to the present invention;

FIG. 5 is a flow chart showing a process flow of species registration, according to the prior art;

FIG. 6 is a schematic drawing of a prober according to the prior art;

FIG. 7 is a drawing showing a method of registering the electrode pads on the prober according to the prior art;

FIG. 8 is a drawing showing a method of aligning the probe needles and detecting height thereof using a prober according to the prior art;

FIG. 9 is a drawing showing registration of arbitrary electrode pads shown in FIG. 7, for an explanation of a problem in the prior art; and

FIG. 10 is a drawing showing registration of arbitrary electrode pads shown in FIG. 8, for an explanation of a problem in the prior art.

### DETAILED DESCRIPTION OF THE INVENTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

The present invention makes a prober recognize probe information of a probe card, and this makes it possible to dispense with all operations on the prober, which have been necessary for the prior art shown in FIG. 5, including alignment of the probe card with a wafer, detection of height of the probe card, and confirmation of probe marks formed on electrode pads.

More specifically, the present invention makes the prober recognize probe information of probe needle for inspection measurement contained by a probe card ((X,Y,Z) coordinates of each probe needle with respect to a reference position of the probe card, diameter of probe ends, probe pressure and designed coordinates of electrode pads) which is measured by a card checker or the like. This allows the probe to automatically recognize positions and height of all probe needles with respect to the electrode pads simply by aligning a reference position of the LSI chip and the reference position of the probe card.

This is successful in dispensing with registration operation, which has been necessary in the prior art, of information such as positions of the electrode pads and probe needles, and realizes probing under complete understanding of the properties of all probe needles. A large saving in the operation time for registering the species also improves the operation rate of the prober. The prober is further successful in obtaining information on all probe needles, and can therefore take part in probe information management which has been done using a probe card checker or the like.

The following paragraphs will describe embodiments of the present invention.

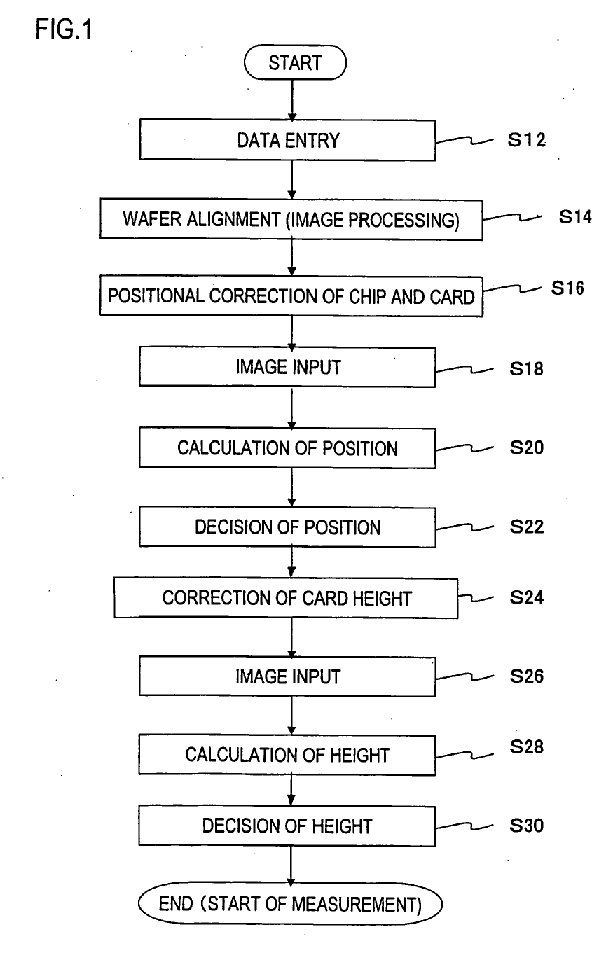

First, a process flow from the entry of data with respect to the probe information up to start of the inspection measurement using the prober of the present invention will be detailed referring to the flow chart in FIG. 1.

(1) Entry of Probe Information to Proper (step S12 in FIG. 1)

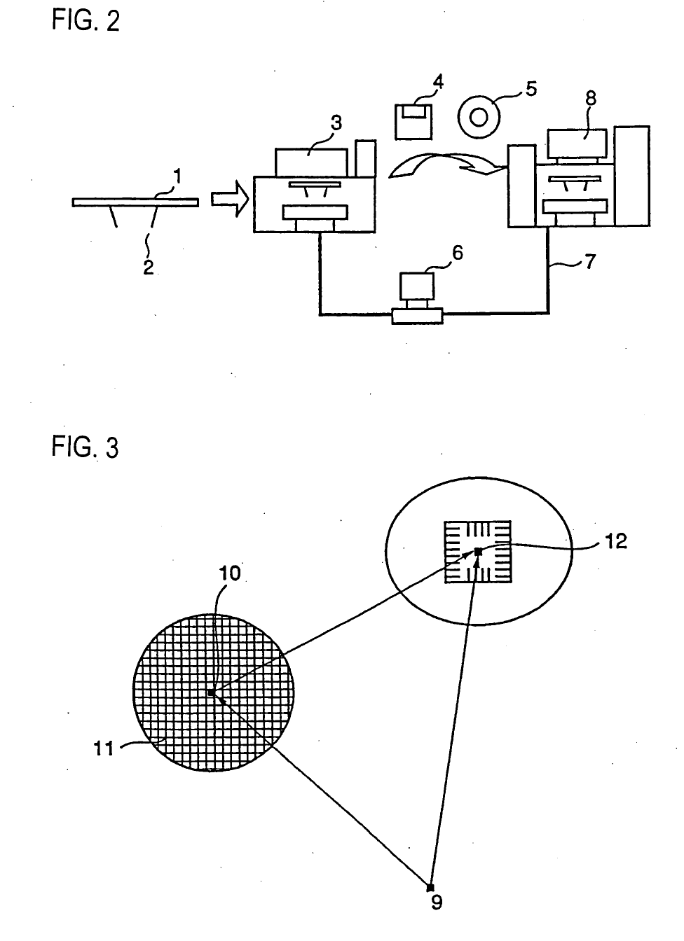

The prober is made recognize the probe information. Typically as shown in FIG. 2, a probe information of probe needles 2 contained by a probe card 1 is acquired using a card checker 3 or the like, and this probe information is then sent to be read by a prober 8.

The information on the probe needles herein may include (X,Y,Z) coordinates of needles with respect to a reference position of the probe card (corresponding to a reference position of LSI chip, for example, center of the chip), diameter of the probe ends, probe pressure, and designed coordinates of the electrode pads. Read-in of the probe information into the prober can be made through a network 7, or through a recording medium such as an FD (flexible disk) 4, CD-ROM 5 or MO (not shown).

(2) Wafer Transfer (not shown) and Alignment (step S14 in FIG. 1)

First, a wafer housed in a wafer case is transferred to a wafer stage, similarly to the step of the prior art described in the above. Then, measurement of wafer thickness and alignment are made using an optical unit such as a CCD camera or a static capacity sensor (step S14).

The measurement of wafer thickness can be made by finding height difference between the surface of the wafer and the surface of the wafer stage referring to, for example, an image input from the optical unit.

The alignment can be made by the prober through θ alignment based on a characteristic patterns such as a specific point or a reference mark in the LSI chip of the wafer, and then by measuring and calculating positions of the wafer center and the reference position of the LSI chip based on the image input by the optical unit. The alignment in the XY direction is made based on results of the calculation.

(3) Correction of Positions of Electrode Pads and Probe Needles (steps S16 to S22 in FIG. 1)

Alignment of the electrode pads with the probe needles will be explained. As shown in FIG. 3, the prober 8 has already acquired the coordinates of all electrode pads and all probe needles based on the probe information. Correction of actual position of the attachment is therefore made with reference to certain arbitrary electrode pads and correspondent probe needles, based on an image information of the wafer obtained by image capturing of the wafer from the top using the optical unit, and based on the probe information. It is to be noted herein that, in FIG. 3, reference numeral 9 denotes an origin of the prober operation, 10 denotes the center of the LSI chip, and 12 denotes the center of the probe needles.

Positions of the electrode pads or probe needles had to manually be specified in the prior art, whereas the present invention can automatically align the optical unit, and can automatically enter the image information of a plane obtained by image capturing from the top direction of the wafer, because the rough positions have already been obtained based on the probe information (step S18 in FIG. 1). Next, a value of two-dimensional coordinate corrected with respect to a reference position is calculated (step S20) based on the image information of the wafer (steps S14, S16), coordinate on the X-Y plane of the wafer (step S14), and based on result of the calculation, the amount of the positional correction is decided (step S22).

(4) Correction of Height of Probe Needles (steps S24 to S30 in FIG. 1)

Height of arbitrary probe needles is adjusted by entering an image information of the ends of the probe needles obtained by image capturing from the upper and lower directions by automatically adjusting position of the optical unit (step S26), by calculating the amount of the height correction of ends of the probe needles, based on XY coordinates of the electrode pads, XY coordinates of the ends of the probe needles (step S28), Z coordinates of the ends of the probe needles and information on the wafer thickness (step S14), and by deciding the amount of the height of the probe needles based on the calculated results.

(5) Correction of Contact Position (not illustrated)

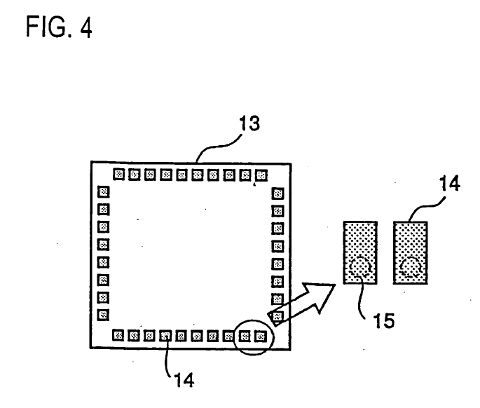

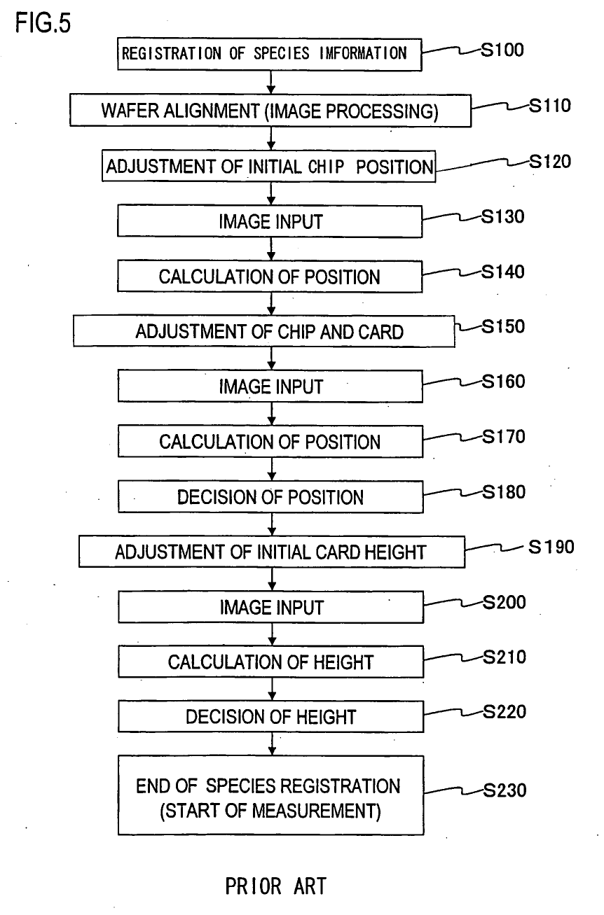

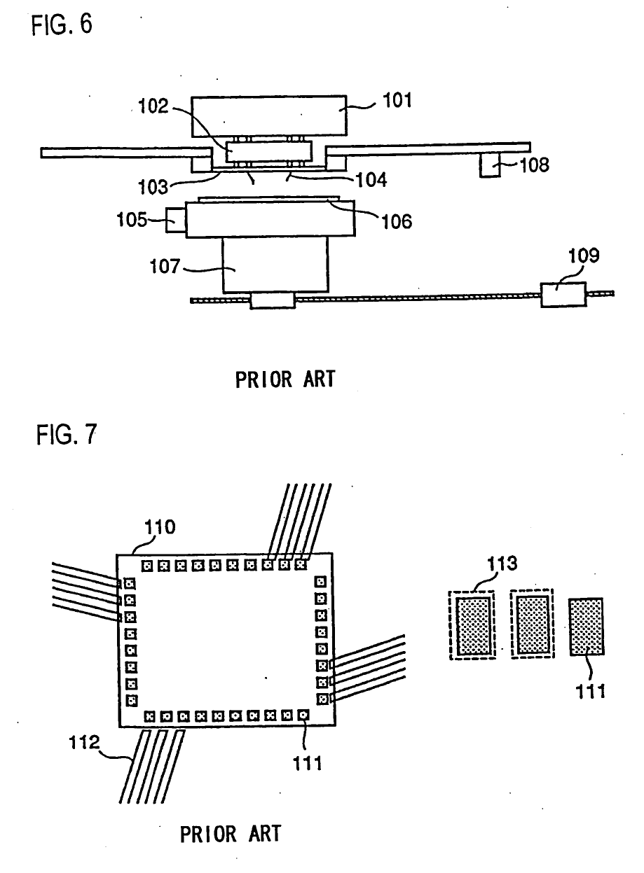

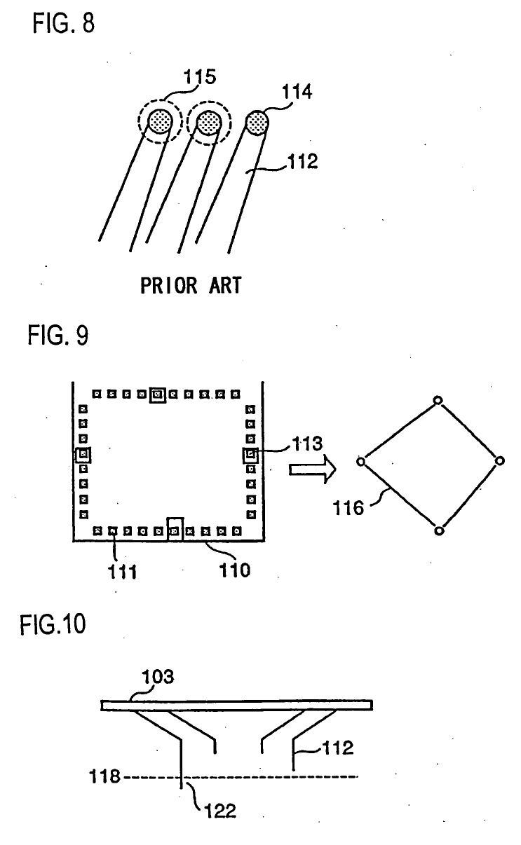

After completion of the alignment and height adjustment, positions of contact are corrected. As shown in FIG. 4, the positional correction is carried out by displaying positions of the probe needles in contact with the electrode pads 14. It is to be noted herein that, in FIG. 4, reference numeral 15 denotes positions shown based on the probe information.

(6) Start of (Inspection) Measurement

Electrical measurement of the LSI chip is carried out by bringing the needle ends of the probe needles into contact with the electrode pads of the LSI chip.

The prior art was only successful in managing positions and height of the probe needles correspondent to the registered electrode pads, whereas the present invention is successful in managing all probe needles of the probe card using the prober.

In an exemplary case where height of the probe needles is to be managed, the prober can manage variation in the height simply by detecting the height only for the probe needles of which end is arranged at the most distant position or the nearest position, respectively, from the probe card in a periodical manner, because the prober has already obtained coordinates of those probe needles.

The prior art has also suffered from that accuracy in the probing depends on the number of registration, because the alignment and height detection are available only for registered electrode pads and probe needles. Whereas the present invention enables the alignment and height detection taking properties of all probe needles into consideration, because the prober preliminarily incorporate all information of the probe needles. This successfully realizes the probing in consideration of properties of the probe needles.

In the prior art, the operator had to manually register the electrode pads and probe needles, whereas the present invention no more needs the registration because the probe card is read by the card checker and thus-obtained probe information is incorporated into the prober, and thereby the prober preliminarily obtains all probe information.

It has been necessary in the prior art to register species using the prober, whereas the species registration on the prober is no more necessary for the present invention by virtue of a system adopted herein in which the probe information is obtained from an external card checker, and thus-obtained probe information is entered to the prober.

It was also necessary for the prior art to form the probe marks on the electrode pads in order to confirm whether the probe needles exactly contact with the registered electrode pads. Whereas in the present invention, it is no more necessary to confirm the probe marks because the positions of the probe needles are displayed on the electrode pads.

It is apparent that the present invention is not limited to the above embodiments, that may be modified and changed without departing from the scope and spirit of the invention.

1. A semiconductor inspection device based on use of probe information, comprising
a card checker reading probe information of probe needles for inspection measurement contained by a probe card; and
a prober automatically recognizing position and height of all probe needles correspondent to electrode pads on an LSI chip, by recognizing said probe information of said probe card read by said card checker, and by making coincidence of a reference position of said LSI chip with a reference position of said probe card.

2. The semiconductor inspection device according to claim 1, wherein said probe information includes (X,Y,Z) coordinates of each probe needle with respect to said reference position of said probe card, diameter of the probe ends, probe pressure, and designed coordinates of the electrode pads.

3. The semiconductor inspection device according to claim 1, wherein said prober obtains information on properties of all probe needles by recognizing position and height of said all probe needles.

4. The semiconductor inspection device according to claim 1, wherein said prober obtains information on coordinates of a probe needle of which end is arranged from the probe card at the most distant position and a probe needle of which end is arranged at the nearest position based on said probe information.

5. A method of inspecting semiconductor based on use of probe information, comprising:
entering into a prober a probe information of probe needles for inspection measurement contained by a probe card;
transferring a wafer to a predetermined position;
making coincidence of a reference position of an LSI chip with a reference position of said probe card based on said predetermined position
correcting position and height of all probe needles correspondent to electrode pads on said LSI chip;
adjusting contact positions of said electrode pads and said probe needles; and
making contact of the probe ends of said probe needles to said electrode pads, to thereby carry out electrical measurement of said LSI chip.

6. The semiconductor inspection method as claimed in claim 5, wherein entry to said prober is made by obtaining said probe information of said probe card by reading using a card checker, and by allowing said prober to read thus obtained probe information.

7. The semiconductor inspection method as claimed in claim 6, wherein said probe information includes coordinates of each probe needle with respect to said reference position of said probe card, diameter of the probe ends, probe pressure, and designed coordinates of the electrode pads.

8. The semiconductor inspection method as claimed in claim 5, wherein entry of said probe needle information to said prober is made through a network.

9. The semiconductor inspection method as claimed in claim 5, wherein entry of said probe needle information to said prober is made through a recording medium.

10. The semiconductor inspection method as claimed in claim 5, wherein the positional correction of said electrode pads and said probe needles is carried out by obtaining coordinates of all electrode pads and all probe needles based on said probe information using said prober; by acquiring, using an optical unit which captures image of state of said probe needles and said electrode pads, an image of arbitrary electrode pads and probe needles correspondent to said electrode pads obtainable by said optical unit; and by correcting actual positions of said arbitrary electrode pad and the correspondent probe needle, based on the image and said probe information.

11. The semiconductor inspection method as claimed in claim 5, wherein the height correction of said probe needles is carried out by acquiring, using an optical unit which captures image of state of said probe needles and said electrode pads, an image of arbitrary probe needles obtainable by said optical unit; and by correcting said probe information in height based on the acquired image.

12. The semiconductor inspection method as claimed in claim 5, wherein the adjustment of said contact positions is carried out while making display of a position of the probe needle in contact with said electrode pad, in an image obtainable by an optical unit which captures image of state of said probe needles and said electrode pads.
